(19) United States
(12) Patent Application Publication
(10) Pub. No.: US 2025/0285947 A1
(43) Pub. Date: Sep. 11, 2025

(54) SEMICONDUCTOR PACKAGE WITH COMBINED LEAD FRAME AND CLIP FRAME

(71) Applicant: Infineon Technologies AG, Neubiberg (DE)

(72) Inventors: Ralf Otremba, Kaufbeuren (DE); Teck Sim Lee, Melaka (MY); Thai Kee Gan, Melaka Tengah (MY)

(21) Appl. No.: 18/597,324

(22) Filed: Mar. 6, 2024

(51) Int. Cl. H01L 23/495; H01L 23/00; H01L 23/31; H01L 25/00; H01L 25/065

(52) U.S. Cl. CPC H01L 23/49562; H01L 23/3107; H01L 23/49503; H01L 24/40; H01L 24/48; H01L 25/0655; H01L 25/50; H01L 2224/40245; H01L 2224/48245; H01L 2924/1815

(57) ABSTRACT

A method of forming a semiconductor package includes providing a first lead frame that comprises a die attach region with a plurality of first contacts and a first clip section that is attached to one or more of the first contacts, performing a first die attach step that mounts a first semiconductor die within the die attach region of the first lead frame, electrically connecting terminals of the first semiconductor die with at least some of the first contacts, providing a second lead frame that includes a die pad and a plurality of second contacts that are attached to the die pad and are vertically offset from the die pad, performing a second die attach step that mounts a second semiconductor die on the die pad, and performing a clip attach step that affixes an upper surface of the second semiconductor die to the first clip section.

### BACKGROUND

Many different applications such as automotive and industrial applications utilize power modules. Power modules may include power conversion circuits such as single and multi-phase half-wave rectifiers, single and multi-phase full-wave rectifiers, voltage regulators, inverters, etc. Integrated power modules (IPMs), also referred to as intelligent power modules, include both power electronic circuitry and the logic circuitry for controlling operation of the power electronic circuitry. Power modules can form part of power efficient solutions to reduce or prevent anthropogenic emissions of greenhouse gases. For instance, hybrid electric vehicles (HEVs) or electric vehicles (EVs) utilize power modules to perform power conversion, inversion, switching, etc., in a power efficient manner. It is desirable to produce integrated power modules at lower cost and higher reliability.

### SUMMARY

A method of forming a semiconductor package is disclosed. According to an embodiment, the method comprises providing a first lead frame that comprises a die attach region with a plurality of first contacts and a first clip section that is attached to one or more of the first contacts, performing a first die attach step that mounts a first semiconductor die within the die attach region of the first lead frame, electrically connecting terminals of the first semiconductor die with at least some of the first contacts, providing a second lead frame that comprises a die pad and a plurality of second contacts that are attached to the die pad and are vertically offset from the die pad, performing a second die attach step that mounts a second semiconductor die on the die pad, and performing a clip attach step that affixes an upper surface of the second semiconductor die to the first clip section.

A semiconductor package is disclosed. According to an embodiment, the semiconductor package comprises a first lead frame that comprises a die attach region with a plurality of first contacts and a first clip section that is attached to one or more of the first contacts, a first semiconductor die mounted on the first lead frame within the die attach region and comprising terminals that are electrically connected with at least some of the first contacts, a second lead frame that comprises a die pad and a plurality of second contacts that are attached to the die pad and are vertically offset from the die pad, and a second semiconductor die mounted on the die pad of the second lead frame and comprising an upper surface that is attached to the first clip section.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1, which includes FIGS. 1A-1E, illustrates a method of forming a semiconductor package, according to an embodiment.

FIG. 2, which includes FIGS. 2A-2B, illustrates a semiconductor package, according to an embodiment. FIG. 2A illustrates a plan-view of the semiconductor package without the package body; and FIG. 2B illustrates a plan-view of the semiconductor package with the package body in translucent form.

FIG. 3, which includes FIGS. 3A-3B, illustrates a semiconductor package, according to an embodiment. FIG. 3A illustrates a plan-view of the semiconductor package without the package body; and FIG. 3B illustrates a plan-view of the semiconductor package with the package body in translucent form.

### DETAILED DESCRIPTION

A semiconductor package with an advantageous combined lead frame and clip configuration and corresponding methods of forming the semiconductor package are described herein. The semiconductor package includes at least two semiconductor dies encapsulated within a package body. In an embodiment, the semiconductor package comprises a power transistor die and a driver die that is configured to control a switching operation of the power transistor die. By utilizing a molded package design, the power module can be produced at significantly lower cost than housing-based power modules that utilize expensive power electronics substrates such as DBC (direct bonded copper) or AMB (active metal brazed) substrates. The semiconductor package includes an advantageous combined clip frame and lead frame structure that accommodates the mounting of a first semiconductor die thereon and forms an electrical interconnect clip that contacts and electrically connects with a surface terminal of a second semiconductor die, which is separately mounted on a different lead frame. This combined clip frame and lead frame structure can be used to effectuate an electrical interconnection between the first and second semiconductor dies (e.g., a gate connection) and to provide a fixed voltage connection (e.g., a source connection) to the second semiconductor die. This combined clip frame and lead frame structure reduces the package footprint and decreases congestion, making the semiconductor package smaller and more cost-effective.

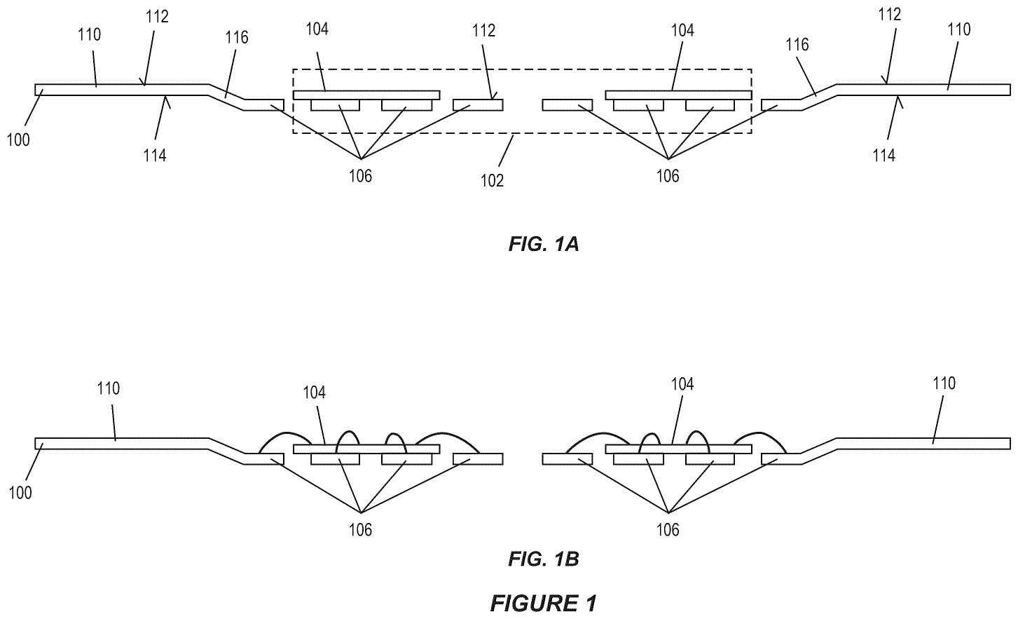

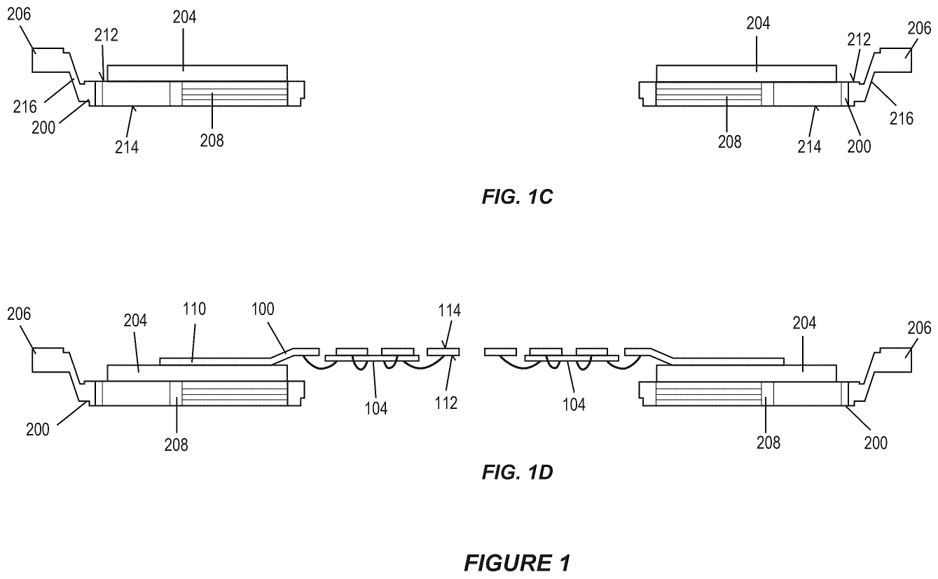

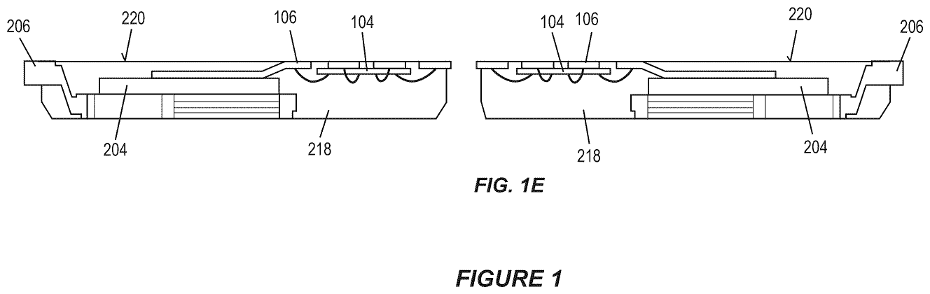

Referring to FIG. 1A, a method of forming a semiconductor package comprises providing a first lead frame 100. The first lead frame 100 may be formed from electrically conductive metals such as copper, aluminum, nickel, silver, palladium, gold, etc., and alloys thereof. The first lead frame 100 may comprise a core metal region that is formed from one or more of the above-mentioned electrically conductive metals and may optionally comprise one or more coatings formed on the core metal region that improve the surface properties of the lead frame, e.g., protection coatings, adhesion coatings, anti-corrosion coatings, etc. The first lead frame 100 may be formed from a uniform thickness sheet of metal that is processed to create the geometry depicted and described herein using metal processing techniques such as stamping, bending, cutting, etching, etc.

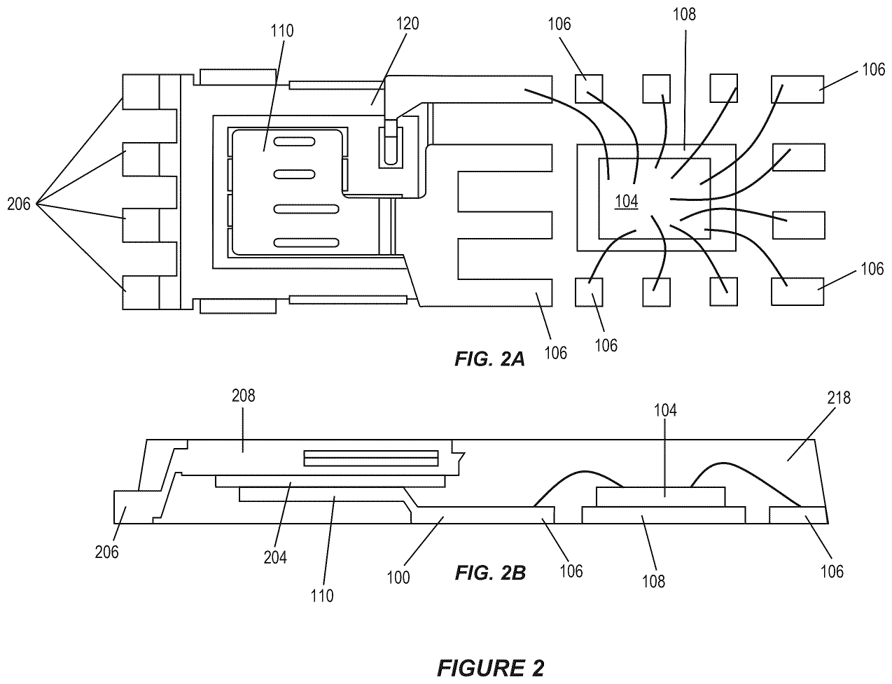

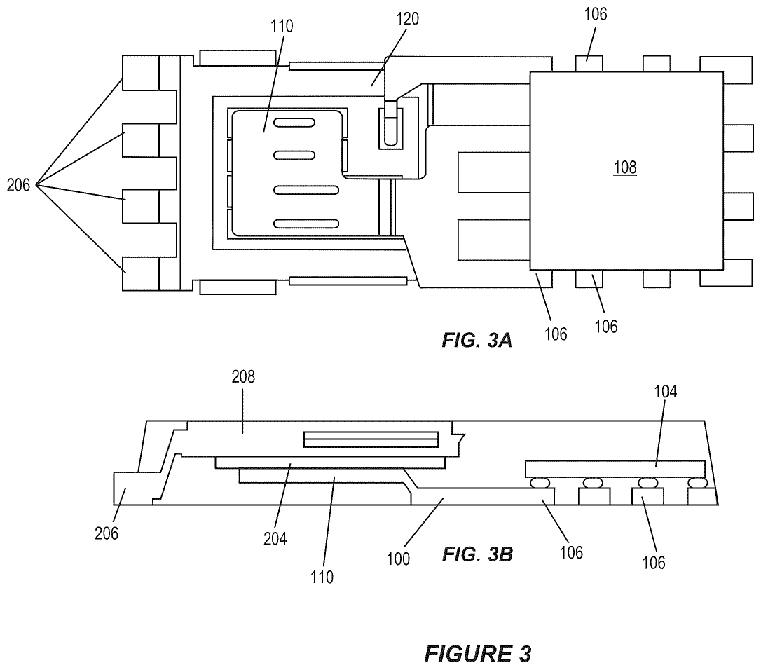

The first lead frame 100 comprises a die attach region 102. The die attach region 102 is a region of the first lead frame 100 that accommodates the mounting of a first semiconductor die 104 thereon. The die attach region 102 comprises a plurality of first contacts 106 arranged within it. The first contacts 106 are isolated islands of metal that are spaced apart from one another and used to form external package contacts in the completed package. For example, the first contacts 106 may be patterned to have a QFN package style arrangement wherein lower surfaces of the first contacts 106 form contact surfaces at a lower side of the completed package. The plurality of first contacts 106 may directly accommodate the mounting of the first semiconductor die 104, e.g., as shown in the embodiment of FIG. 3. Alternatively, the die attach region 102 may additionally comprise a die pad 108 that is larger than the first contacts 106 and accommodates the mounting of the first semiconductor die 104, e.g., as shown in the embodiment of FIG. 2.

The first lead frame 100 further comprises a first clip section 110 that is attached to one or more of the first contacts 106. The first clip section 110 is a lateral span of metal that is configured to be attached with an upper surface terminal of a second semiconductor die 204 and form an electrical connection thereto. Thus, the first clip section 110 may have a generally planar geometry. As will be described in further detail below, the plan-view geometry of the first clip section 110 may be adapted to a particular terminal profile of the second semiconductor die 204.

According to an embodiment, the die attach region 102 comprising the plurality of first contacts 106 is vertically offset from the first clip section 110. That is, the upper surface 112 of the first lead frame 100 in the die attach region 102 extends along a first plane, and the upper surface 112 of the first lead frame 100 in the first clip section 110 extends along a second plane that is vertically offset from the first plane. Separately or in combination, the lower surface 114 of the first lead frame 100 in the die attach region 102 may extend along a third plane, and the lower surface 114 of the first lead frame 100 in the first clip section 110 may extend along a fourth plane that is vertically offset from the third plane. In a lateral region of the first lead frame 100 between the die attach region 102 and the first clip section 110, the first lead frame 100 comprises a transitional span 116 that is angled relative to the die attach region 102 and the first clip section 110.

The method further comprises performing a first die attach step that mounts a first semiconductor die 104 within the die attach region 102 of the first lead frame 100. The first semiconductor die 104 may be mounted using an adhesive, e.g., solder, sinter, glue, tape, etc. In the case of a lateral device, the lower surface of the first semiconductor die 104 may be electrically inactive and hence the connection between the first semiconductor die 104 and the first lead frame 100 may be purely mechanical. Alternatively, the first semiconductor die 104 may comprise one or more terminals disposed on its lower surface and the connection between the first semiconductor die 104 and the first lead frame 100 may be an electrical connection, e.g., a soldered or sintered connection.

Referring to FIG. 1B, the method further comprises electrically connecting terminals of the first semiconductor die 104 with at least some of the first contacts 106. In the depicted embodiment, the terminals of the first semiconductor die 104 are disposed on an upper surface of the first semiconductor die 104 that faces away from the first lead frame 100, and the electrical connections are formed by bond wire connections between the upper surface of the first semiconductor die 104 and the plurality of first contacts 106. More generally, other types of electrical interconnect elements, e.g., ribbons, clips, etc., may be used to provide these electrical connections.

Referring to FIG. 1C, the method of forming the semiconductor package comprises providing a second lead frame 200. The second lead frame 200 may be formed from electrically conductive metals such as copper, aluminum, nickel, silver, palladium, gold, etc., and alloys thereof. The second lead frame 200 may comprise a core metal region that is formed from one or more of the above-mentioned electrically conductive metals and may optionally comprise one or more coatings on the core metal region that improve the surface properties of the lead frame, e.g., protection coatings, adhesion coatings, anti-corrosion coatings, etc. The second lead frame 200 may be formed from a uniform thickness sheet of metal that is processed to create the geometry depicted and described herein using metal processing techniques such as stamping, bending, cutting, etching, etc.

The second lead frame 200 comprises a die pad 208. The second die pad 208 is a planar structure that is sufficiently large to accommodate the mounting of the second semiconductor die 204 thereon. The second lead frame 200 comprises a plurality of second contacts 206 that are attached to the second die pad 208. The second contacts 206 form external package contacts in the completed package. The second contacts 206 may form elongated leads that are configured to protrude out from an encapsulant body. Alternatively, the second contacts 206 may form flat surfaces that are coplanar or substantially coplanar with an encapsulant, i.e., the contacts of a so-called “no-lead” package. More generally, the completed semiconductor package may have any package type.

According to the depicted embodiment, the second contacts 206 are vertically offset from the second die pad 208. That is, the upper surface 212 of the second lead frame 200 in the second die pad 208 extends along a first plane, and the upper surface 212 of the second lead frame 200 at the second contacts 206 extends along a second plane that is vertically offset from the first plane. Separately or in combination, the lower surface 214 of the second lead frame 200 in the second die pad 208 may extend along a third plane, and the lower surface 214 of the second lead frame 200 at the second contacts 206 may extend along a fourth plane that is vertically offset from the third plane. In a lateral region of the second lead frame 200 between the second die pad 208 and the second contacts 206, the second lead frame 200 comprises a transitional span that is angled relative to the second die pad 208 and the second contacts 206.

The method of forming the semiconductor package comprises a second die attach step that mounts a second semiconductor die 204 on the second die pad 208. The second semiconductor die 204 may be mounted using an adhesive, e.g., solder, sinter, glue, etc. According to an embodiment, the second semiconductor die 204 comprises a terminal disposed on a lower surface of the second semiconductor die 204 that faces the second die pad 208 and the mounting process forms an electrical connection between this terminal and the second die pad 208.

According to an embodiment, the second die attach step comprises a diffusion soldering technique. Diffusion soldering refers to a technique whereby a very thin, e.g., less than or equal to 50 μm, 40 μm, 30 μm, 20 μm, 10 μm, 5 μm, 1 μm, etc., layer of solder material is provided in between two metal joining partners, and the soldering process causes metal atoms from the joining partners to diffuse into the thin layer solder material, thereby creating a soldered joint with intermetallic phases. These intermetallic phases have a higher melting temperature than the solder temperature of the diffusion soldering process and create a stable mechanical bond. Examples of diffusion soldering techniques are described in U.S. Pat. Nos. 11,605,608, 11,610,861, and 11,764,185, the content of each document being incorporated by reference herein in their entirety.

Referring to FIG. 1D, the method of forming the semiconductor package comprises a clip attach step that affixes an upper surface of the second semiconductor die 204 to the first clip section 110 of the first lead frame 100. The clip attach step comprises orienting the first lead frame 100 such that the upper surface 112 of the first lead frame 100 faces the second lead frame 200. For example, the steps described above with reference to FIGS. 1A and 1B may be performed with the first lead frame 100 arranged on a temporary carrier (not shown) and the upper surface 112 of the first lead frame 100 facing away from the temporary carrier. Meanwhile, the second die attach step described with reference to FIG. 1C may be performed with the second lead frame 200 arranged on a second temporary carrier (not shown) and the upper surface 212 of the second lead frame 200 facing away from the second temporary carrier. Once the second die attach step is completed, the first lead frame 100 with the first semiconductor die 104 disposed thereon may be flipped upside down and arranged over the second lead frame 200. The clip attach step orients the first lead frame 100 such that the first clip section 110 overlaps with the upper surface of the second semiconductor die 204. Subsequently, an attachment process is performed to affix the first clip section 110 with the second semiconductor die 204. Generally speaking, this attachment process may use any type of adhesive, e.g., solder, sinter, glue, tape, etc. According to an embodiment, the second semiconductor die 204 comprises a terminal disposed on an upper surface of the second semiconductor die 204 that faces away from the second die pad 208 and the clip attach step forms an electrical connection between this terminal and the first clip section 110. According to an embodiment, the second die attach step comprises a diffusion soldering technique. This diffusion soldering technique may be identical to the diffusion soldering technique used in the second die attach step that mounts the second semiconductor die 204 on the second die pad 208, as described above. Optionally, these two steps may be performed simultaneously, i.e., using a common reflow step.

According to an embodiment, after performing the clip attach step, lower surfaces of the first contacts 106 are substantially coplanar with lower surfaces of the second contacts 206. That is, the first lead frame 100 and the second lead frame 200 are arranged such that the lower package contacting surfaces of these two structures are aligned along a single plane. In this way, the first contacts 106 and the second contacts 206 can be aligned at the lower side of an SMD (surface mount device) type package. The substantially coplanar arrangement of the first and second contacts 106, 206 can be realized through selection of the offset distance between the first contacts 106 and the first clip section 110 as well as the offset distance between the second die pad 208 and the second contacts 206, while accounting for the thickness of the second semiconductor die 204.

Referring to FIG. 1E, the method of forming the semiconductor package comprises forming a package body 218 of electrically insulating encapsulant material that encapsulates the first semiconductor die 104 and the second semiconductor die 204. According to an embodiment, the package body 218 is formed by a molding process, e.g., injection molding, compression molding, transfer molding, etc. The electrically insulating encapsulant material used to form the package body 218 may be a plastic material formed from an organic resin such as an epoxy resin. The encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the encapsulant, as appropriate.

After forming the package body 218 the plurality of first contacts 106 and the plurality of second contacts 206 are exposed from the package body 218. As shown, the package body 218 is formed with a lower surface 220 that is coextensive with the lower surfaces of the first contacts 106 and the lower surfaces of the second contacts 206. In this way, a so-called SMD configuration is realized, wherein the first contacts 106 form a group of electrically isolated islands that are independently accessible at one side of the package, and the second contacts 206 form a second group of contacts that are accessible at another side of the package.

After performing the processing steps that form the package body 218, a singulation step may be performed to create individual semiconductor packages. The singulation step may comprise cutting, e.g., mechanical sawing, laser ablation, chemical etch, etc., to detach any parts of the first and second lead frames 100, 200 and the package body 218, if necessary. FIG. 1E shows two identical semiconductor packages created from symmetrical first and second lead frames 100, 200 with identical processing steps being formed at each package site. In practice, many numbers of identical semiconductor packages may be produced using parallel processing techniques.

Referring to FIG. 2, that may be formed according to the above-described method is shown, according to an embodiment. The semiconductor package of FIG. 2 comprises a first semiconductor die 104 mounted on the first lead frame 100 and a second semiconductor die 204 mounted on the second die pad 208 of the second lead frame 200. According to an embodiment, the first semiconductor die 104 is a lateral device comprising terminals disposed on an upper surface that faces away from the first lead frame 100 and the second semiconductor die 204 is a vertical device comprising terminals disposed both on an upper surface that faces away from the second lead frame 100 and on a lower surface that faces away from the second lead frame 100. In a more particular embodiment of this, the second semiconductor die 204 is configured as a vertical power transistor, and the first semiconductor die 104 is a logic device that is configured to control a switching operation of the second semiconductor die 204. In that case, the second semiconductor die 204 may comprise a first load terminal and a control terminal are disposed on an upper surface of the second semiconductor die 204, and the second semiconductor die 204 comprises a second load terminal disposed on a lower surface of the second semiconductor die 204. The first and second load terminals may respectively correspond to the source and drain terminals in the case of a MOSFET (or vice-versa) and may respectively correspond to the emitter and collector terminals in the case of an IGBT (or vice-versa). The control terminal may correspond to the gate terminal in these examples. In embodiments wherein the second semiconductor die 204 is configured as a vertical power transistor, the second semiconductor die 204 may be formed in different device technologies. In an embodiment, the second semiconductor die 204 is a silicon-based device. In another embodiment, the second semiconductor die 204 is a silicon carbide (SiC) based device. In another embodiment, the second semiconductor die 204 is a III-V nitride device, such as a GaN device.

In the depicted embodiment, the first load terminal of the second semiconductor die 204 is electrically connected with the first clip section 110, which in turn forms a direct connection with a group of the first contacts 106, thereby providing one of the fixed voltage terminals of the device. Meanwhile, the second load terminal of the second semiconductor die 204 is electrically connected to the second die pad 208 of the second lead frame 200, which in turn forms a direct connection with the second contacts 206, thereby providing a second one of the fixed voltage terminals of the device.

In the depicted embodiment, the first lead frame further comprises a second clip section 120 that is attached to one or more of the first contacts 106 and is spaced apart from the first clip section 112. The second clip section 120 may be disposed on a different vertical plane as the die attach region 102 in a similarly manner as the first clip section 110 described above. The control terminal of the second semiconductor die 204, e.g., the gate terminal, is electrically connected with the second clip section 120, which in turn is electrically connected with a terminal from the first semiconductor die 104, thereby providing a control connection between the first semiconductor die 104 and the second semiconductor die 204 for controlling the switching operation of the second semiconductor die 204. Additionally, the second clip section 120 is connected with one of the first contacts 106, thereby providing electrical access to this terminal if needed. In this configuration, the group of the first contacts 106 that are connected with the first load terminal and first contact 106 that is connected to the control terminal of the second semiconductor die 204 are arranged within a central part of the semiconductor package, which may be electrically accessed from an underside of the semiconductor package, e.g., by mounting the semiconductor package on a carrier such as a PCB. Optionally, at least some of the first contacts 106 that are connected with the first load terminal and/or the control terminal may be exposed at a sidewall of the package body 218, thereby allowing for a side connection.

Referring to FIG. 3, a semiconductor package is depicted, according to another embodiment. The semiconductor package of FIG. 3 is identical to that of FIG. 2 with the following differences. Whereas the semiconductor package of FIG. 2 is configured with the first semiconductor die 104 having wire bond connections, in the semiconductor package of FIG. 3 the first semiconductor die 104 is mounted in a flip-chip configuration. In this configuration, the terminals of the first semiconductor die 104 are disposed on a lower surface of the first semiconductor die 104 that faces the first lead frame. The terminals of the first semiconductor die 104 are electrically connected with the plurality of first contacts 106 by flip-chip connections. For example, the flip-chip connections may be provided by solder balls that are formed on the lower surface of the first semiconductor die 104 and joined with the plurality of first contacts 106 by a soldering process. As can be seen, the first lead frame 100 may be adapted accordingly. In particular, the die attach region 102 of the first lead frame 100 may be devoid of a dedicated die pad 108. Instead, the first semiconductor die 104 is mounted directly on the plurality of first contacts 106 so that each of the terminals may be electrically contacted.

Embodiments of a semiconductor package described herein comprise semiconductor dies incorporated into the package. These semiconductor dies may be singulated from a semiconductor wafer (not shown), e.g. by sawing, prior to package production. In general, the semiconductor wafer and therefore the resulting semiconductor die may be made of any semiconductor material suitable for manufacturing a semiconductor device. Examples of such materials include, but are not limited to, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), etc. In general, the semiconductor die can be any active or passive electronic component. Examples of these devices include power semiconductor devices, such as power MISFETs (Metal Insulator Semiconductor Field Effect Transistors) power MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors), power bipolar transistors or power diodes such as, e.g., PIN diodes or Schottky diodes, etc. Other examples of these devices include logic devices, such as microcontrollers, processors, field programmable gate arrays (FPGAs), memory circuits, level shifters, sensor devices, etc. One or more of the semiconductor dies can be configured as a so-called lateral device. In this configuration, the terminals of the semiconductor die are provided on a single main surface and the semiconductor die is configured to conduct in a direction that is parallel to the main surface of the semiconductor die. Alternatively, one or more of the semiconductor dies can be configured as a so-called vertical device. In this configuration, the terminals of the semiconductor die are provided on opposite facing main and rear surface and the semiconductor die is configured to conduct in a direction that is perpendicular to the main surface of the semiconductor die. The semiconductor dies disclosed herein may be power devices. The term power device refers to a discrete semiconductor die that is rated to accommodate voltages and/or currents associated with power applications, e.g., voltages of at least 100 V (volts), at least 600 V, at least 1200V or more and/or rated to accommodate currents of at least 1 A (amperes), at least 10 A, at least 50 A, at least 100 A or more. Power devices include power transistors, e.g., MOSFETS, HEMTs, IGBTs, etc., thyristors and diodes.

The term “package type” as used herein refers to the particular construction of a semiconductor package, in particular the arrangement and structure of the external contacts, the arrangement and structure of the carrier structure that accommodates the semiconductor dies, and the arrangement and structure of the encapsulant material. A variety of different package types exist within the semiconductor industry. Examples of these package types include the so-called TO (transistor outline) package type, the DIP (dual in-line package), LGA (land grid array) package type, MCM (multi-chip module) package type, LCC (leaded chip carrier) package type, PGA (pin grid array) package type, CFP (ceramic flat pack) package type, QFN (quad flat no-leads) package type, TSOP (thin small-outline package) package type and WLB (Wafer Level Ball Grid Array) package type.

The term “substantially” as used herein describes a nominal relationship between elements to the extent practically achievable and/or necessary for a given application. The “substantially” encompasses deviation from a nominal or target value that may result from processing tolerances or other factors tending to cause deviation from the nominal or target value.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

Although the present disclosure is not so limited, the following numbered examples demonstrate one or more aspects of the disclosure.

Example 1. A method of forming a semiconductor package, the method comprising: providing a first lead frame that comprises a die attach region with a plurality of first contacts and a first clip section that is attached to one or more of the first contacts; performing a first die attach step that mounts a first semiconductor die within the die attach region of the first lead frame; electrically connecting terminals of the first semiconductor die with at least some of the first contacts; providing a second lead frame that comprises a die pad and a plurality of second contacts that are attached to the die pad and are vertically offset from the die pad; performing a second die attach step that mounts a second semiconductor die on the die pad; and performing a clip attach step that affixes an upper surface of the second semiconductor die to the first clip section.

Example 2. The method of example 1, wherein the first die attach step mounts the first semiconductor die on an upper surface of the first lead frame, and wherein the clip attach step comprises orienting the first lead frame such that the upper surface of the first lead frame faces the second lead frame and such that the first clip section overlaps with the upper surface of the second semiconductor die.

Example 3. The method of example 2, wherein the plurality of first contacts is vertically offset from the first clip section, and wherein after the clip attach step lower surfaces of the first contacts are substantially coplanar with lower surfaces of the second contacts.

Example 4. The method of example 3, further comprising forming a package body of electrically insulating encapsulant material that encapsulates the first semiconductor die and the second semiconductor die, and wherein after forming the package body lower surfaces of the first contacts and lower surfaces of the second contacts are substantially coplanar with a lower side of the package body.

Example 5. The method of example 1, wherein at least one of the second die attach step and the clip attach step comprises diffusion soldering.

Example 6. The method of example 1, wherein electrically connecting terminals of the first semiconductor die with each of the first contacts comprises forming bond wire connections between an upper surface of the first semiconductor die and the plurality of first contacts.

Example 7. The method of example 1, wherein electrically connecting terminals of the first semiconductor die with each of the first contacts comprises providing flip chip connections between a lower surface of the first semiconductor die and the plurality of first contacts.

Example 8. The method of example 1, wherein the second semiconductor die is a power transistor device comprising a control terminal, a first load terminal, and a second load terminal.

Example 9. The method of example 8, wherein the second semiconductor die is a silicon carbide device.

Example 10. The method of example 8, wherein the second semiconductor die is a gallium nitride device.

Example 11. The method of example 8, wherein the first load terminal is disposed on an upper surface of the second semiconductor die, wherein the second load terminal is disposed on a lower surface of the second semiconductor die, and wherein the method comprises: electrically connecting the first load terminal of the second semiconductor die with the first clip section; and electrically connecting the second load terminal of the second semiconductor die with the die pad.

Example 12. The method of example 11, wherein the first semiconductor die is a logic device that is configured to control a switching operation of the second semiconductor die.

Example 13. The method of example 12, wherein the control terminal is disposed on the upper surface of the second semiconductor die, wherein the first lead frame further comprises a second clip section that is attached to one or more of the first contacts, and wherein the method further comprises electrically connecting the control terminal of the second semiconductor die with the first semiconductor die via the second clip section.

Example 14. A semiconductor package, comprising: a first lead frame that comprises a die attach region with a plurality of first contacts and a first clip section that is attached to one or more of the first contacts; a first semiconductor die mounted on the first lead frame within the die attach region and comprising terminals that are electrically connected with at least some of the first contacts; a second lead frame that comprises a die pad and a plurality of second contacts that are attached to the die pad and are vertically offset from the die pad; and a second semiconductor die mounted on the die pad of the second lead frame and comprising an upper surface that is attached to the first clip section.

Example 15. The semiconductor package of example 14, further comprising: a package body of electrically insulating encapsulant material that encapsulates the first semiconductor die and the second semiconductor die, and wherein the plurality of first contacts and the plurality of second contacts are exposed from the package body.

Example 16. The semiconductor package of example 15, wherein lower surfaces of the first contacts and lower surfaces of the second contacts are substantially coplanar with a lower side of the package body.

Example 17. The semiconductor package of example 16, wherein an upper side of the die pad from the second lead frame is exposed at an upper side of the encapsulant body that is opposite from the lower side of the encapsulant body.

Example 18. The semiconductor package of example 16, wherein the semiconductor package is configured as a QFN (quad flat no-leads) type package.

Example 19. The semiconductor package of example 14, wherein the terminals of the first semiconductor die are disposed on an upper surface of the first semiconductor die and are electrically connected with the plurality of first contacts by bond wire connections.

Example 20. The semiconductor package of example 14, wherein the terminals of the first semiconductor die are disposed on a lower surface of the first semiconductor die and are electrically connected with the plurality of first contacts by flip-chip connections.

Example 21. The semiconductor package of example 14, wherein the second semiconductor die is a power transistor device comprising a control terminal, a first load terminal, and a second load terminal.

Example 22. The semiconductor package of example 20, wherein the second semiconductor die is a silicon carbide device.

Example 23. The semiconductor package of example 20, wherein the second semiconductor die is a gallium nitride device.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of forming a semiconductor package, the method comprising:
providing a first lead frame that comprises a die attach region with a plurality of first contacts and a first clip section that is attached to one or more of the first contacts;
performing a first die attach step that mounts a first semiconductor die within the die attach region of the first lead frame;
electrically connecting terminals of the first semiconductor die with at least some of the first contacts;
providing a second lead frame that comprises a die pad and a plurality of second contacts that are attached to the die pad and are vertically offset from the die pad;
performing a second die attach step that mounts a second semiconductor die on the die pad; and
performing a clip attach step that affixes an upper surface of the second semiconductor die to the first clip section.

2. The method of claim 1, wherein the first die attach step mounts the first semiconductor die on an upper surface of the first lead frame, and wherein the clip attach step comprises orienting the first lead frame such that the upper surface of the first lead frame faces the second lead frame and such that the first clip section overlaps with the upper surface of the second semiconductor die.

3. The method of claim 2, wherein the plurality of first contacts is vertically offset from the first clip section, and wherein after the clip attach step lower surfaces of the first contacts are substantially coplanar with lower surfaces of the second contacts.

4. The method of claim 3, further comprising forming a package body of electrically insulating encapsulant material that encapsulates the first semiconductor die and the second semiconductor die, and wherein after forming the package body, lower surfaces of the first contacts and lower surfaces of the second contacts are substantially coplanar with a lower side of the package body.

5. The method of claim 1, wherein at least one of the second die attach step and the clip attach step comprises diffusion soldering.

6. The method of claim 1, wherein electrically connecting terminals of the first semiconductor die with each of the first contacts comprises forming bond wire connections between an upper surface of the first semiconductor die and the plurality of first contacts.

7. The method of claim 1, wherein electrically connecting terminals of the first semiconductor die with each of the first contacts comprises providing flip chip connections between a lower surface of the first semiconductor die and the plurality of first contacts.

8. The method of claim 1, wherein the second semiconductor die is a power transistor device comprising a control terminal, a first load terminal, and a second load terminal.

9. The method of claim 8, wherein the second semiconductor die is a silicon carbide device.

10. The method of claim 8, wherein the second semiconductor die is a gallium nitride device.

11. The method of claim 8, wherein the first load terminal is disposed on an upper surface of the second semiconductor die, wherein the second load terminal is disposed on a lower surface of the second semiconductor die, and wherein the method comprises:
electrically connecting the first load terminal of the second semiconductor die with the first clip section; and
electrically connecting the second load terminal of the second semiconductor die with the die pad.

12. The method of claim 11, wherein the first semiconductor die is a logic device that is configured to control a switching operation of the second semiconductor die.

13. The method of claim 12, wherein the control terminal is disposed on the upper surface of the second semiconductor die, wherein the first lead frame further comprises a second clip section that is attached to one or more of the first contacts, and wherein the method further comprises electrically connecting the control terminal of the second semiconductor die with the first semiconductor die via the second clip section.

14. A semiconductor package, comprising:
a first lead frame that comprises a die attach region with a plurality of first contacts and a first clip section that is attached to one or more of the first contacts;
a first semiconductor die mounted on the first lead frame within the die attach region and comprising terminals that are electrically connected with at least some of the first contacts;
a second lead frame that comprises a die pad and a plurality of second contacts that are attached to the die pad and are vertically offset from the die pad; and
a second semiconductor die mounted on the die pad of the second lead frame and comprising an upper surface that is attached to the first clip section.

15. The semiconductor package of claim 14, further comprising:
a package body of electrically insulating encapsulant material that encapsulates the first semiconductor die and the second semiconductor die, and
wherein the plurality of first contacts and the plurality of second contacts are exposed from the package body.

16. The semiconductor package of claim 15, wherein lower surfaces of the first contacts and lower surfaces of the second contacts are substantially coplanar with a lower side of the package body.

17. The semiconductor package of claim 16, wherein an upper side of the die pad from the second lead frame is exposed at an upper side of the package body that is opposite from the lower side of the package body.

18. The semiconductor package of claim 16, wherein the semiconductor package is configured as a QFN (quad flat no-leads) type package.

19. The semiconductor package of claim 14, wherein the terminals of the first semiconductor die are disposed on an upper surface of the first semiconductor die and are electrically connected with the plurality of first contacts by bond wire connections.

20. The semiconductor package of claim 14, wherein the terminals of the first semiconductor die are disposed on a lower surface of the first semiconductor die and are electrically connected with the plurality of first contacts by flip-chip connections.

21. The semiconductor package of claim 14, wherein the second semiconductor die is a power transistor device comprising a control terminal, a first load terminal, and a second load terminal.

22. The semiconductor package of claim 20, wherein the second semiconductor die is a silicon carbide device.

23. The semiconductor package of claim 20, wherein the second semiconductor die is a gallium nitride device.
